(19) United States
(12) Patent Application Publication
(10) Pub. No.: US 2010/0135752 A1
(43) Pub. Date: Jun. 3, 2010

(54) ROBOT DEVICE AND CONTROL METHOD THEREOF

(76) Inventor: Shinichi IMAI, Ibara-shi (JP)

Correspondence Address: MARK D. SARALINO (GENERAL);RENNER, OTTO, BOISSELLE & SKLAR, LLP, 1621 EUCLID AVENUE, NINETEENTH FLOOR, CLEVELAND, OH, 44115-2191, US

(21) Appl. No.: 12/624,511

(22) Filed: Nov. 24, 2009

(30) Foreign Application Priority Data
Dec. 2, 2008 (JP) 2008-307732

(51) Int. Cl. H01L 21/677; G06F 19/00

(52) U.S. Cl. 414/217; 700/245

(57) ABSTRACT

The robot device according to this invention includes an arm mechanism, multiple hand mechanisms, and a control unit. The arm mechanism has its base end rotatably supported on a base point set in a predetermined position in the horizontal plane, and its free end moves among orthogonal coordinates in the horizontal plane. Each of the multiple hand mechanisms has its support end rotatably supported by the free end, and its holding end moves among polar coordinates in the horizontal plane. The holding ends hold substrates. The control unit drives the arm mechanism so that the free end approaches a base line connecting a base point with the center of a stage without passing over the base point, and drives the multiple hand mechanisms so that an export holding end moves along the base line and a non-export holding end separates from the export holding end.

### CROSS REFERENCE

This Nonprovisional application claims priority under 35 U.S.C. §119(a) on Patent Application No. 2008-307732 filed in Japan on Dec. 2, 2008, the entire contents of which are hereby incorporated by reference.

### BACKGROUND OF THE INVENTION

This invention relates to a robot device, installed within a processing chamber such as a vacuum chamber, that transports substrates such as, for example, semiconductor substrates, liquid crystal glass substrates, and magnetic disks between a stage installed outside of the processing chamber and the interior of the processing chamber, and also relates to a control method for such a robot device.

The manufacture of semiconductor devices, liquid crystal displays, magnetic disks, and so on involves processing the precision substrates used as the materials within a processing chamber. A vacuum chamber is an example of such a processing chamber. The substrates are transported between a stage installed outside of the processing chamber and the interior of the processing chamber by a robot device installed within the processing chamber.

As described in, for example, JP 2003-188231A, a conventional robot device that transports substrates between a stage and the interior of a processing chamber is provided with an arm mechanism and a hand mechanism. The arm mechanism includes a lower arm, an upper arm, a lower motor, and an upper motor. The hand mechanism includes a hand and a hand motor.

One end section of each of the lower arm and the upper arm is used as an axial support end, with the two arms supported relative to each other by a shaft. The end section of the lower arm opposite to the shaft support end is a base end axially supported central to a base shaft set within a horizontal surface. Meanwhile, the end section of the upper arm opposite to the shaft support end is a free end that axially supports one end section of the hand serving as an axial support end. The end section of the hand opposite to the shaft support end thereof is a holding end that holds a substrate.

The lower motor rotates the lower arm central to the base axis. The upper motor, meanwhile, rotates the upper arm central to the shaft. The hand motor rotates the hand central to the free end. When the lower motor and the upper motor are driven individually, the free end moves among orthogonal coordinates within the horizontal surface. Then, when the hand motor is driven, the holding end moves among polar coordinates. When transporting a substrate from within the chamber to a stage, the lower motor, upper motor, and hand motor are driven individually so that the substrate is moved in a straight line following a base line connecting a base point to the center of the stage, thereby minimizing the movement distance.

The conventional robot device is provided with multiple hand mechanisms for the purpose of streamlining the substrate processing, and is capable of importing and exporting multiple substrates into and out of the processing chamber simultaneously. Meanwhile, even if a substrate is held by each holding end of a robot device provided with multiple hand mechanisms, there are cases where, due to processing issues, only some of the multiple substrates stored within the chamber are to be transported to the stage. It is necessary to move the substrates in a straight line following a base line connecting a base point to the center of the stage in such cases as well.

However, the conventional robot device and control method thereof have not sufficiently considered interference between the substrates that are not transported and the inner wall of the processing chamber when only some of multiple substrates stored within the chamber are transported to the stage. For this reason, there has been a problem in that the size of the processing chamber cannot be sufficiently reduced.

For example, when a holding end holding a substrate to be transported is moved with the support end along a straight line that follows a base line, the substrates that are not to be transported will come into contact with the inner wall of the processing chamber if the radius of the processing chamber is shorter than the length from the support end to the outer circumference of the substrate in the lengthwise direction of the hand. For this reason, the radius of the processing chamber cannot be shortened beyond the length from the support end to the outer circumference of the substrate in the lengthwise direction of the hand, and thus the size of the processing chamber cannot be sufficiently reduced.

It is thus an object of this invention to provide a robot device that moves the free end of an arm axially supporting a support section of a hand among orthogonal coordinates while moving a holding end of the hand among polar coordinates and that, when exporting only some of substrates stored within a processing chamber, can prevent the inner wall of the processing chamber from interfering with the remaining substrates, and that can realize a sufficient reduction in the size of the processing chamber, as well as to provide a control method for such a robot device.

### SUMMARY OF THE INVENTION

The robot device according to this invention includes an arm mechanism, multiple hand mechanisms, and a control unit, and exports only some of multiple substrates held by the holding ends of at least two of the multiple hand mechanisms from within a is processing chamber to a stage. The arm mechanism has its base end rotatably supported on a base point set in a predetermined position in the horizontal plane and its free end moves among orthogonal coordinates in the horizontal plane. Each of the multiple hand mechanisms has its support end rotatably supported by the free end, and its holding end moves among polar coordinates in the horizontal plane. The holding ends hold substrates. The control unit drives the arm mechanism so that the free end approaches a base line connecting a base point with the center of a stage without passing over the base point, and drives the multiple hand mechanisms so that an export holding end holding a substrate to be exported moves along the base line and a non-export holding end holding a substrate not to be exported separates from the export holding end.

At the same time as the free end of the arm mechanism approaches the base line connecting the base point with the center of the stage without passing over the base point, the export holding end on one of the hand mechanisms moves along the base line, and the non-export holding end on the other hand mechanism separates from the export holding end. Because the free end moves among orthogonal coordinates so as to approach the base line without passing over the base point while the export holding end moves among polar coordinates central to the free end, the substrate moves with the export holding end along the base line in the direction of the stage. Because the free end, which is the center of the movement among polar coordinates when the non-export holding end separates from the export holding end, does not pass over the base point, substrates will not come into contact with the inner wall of the processing chamber even in the case where the radius of the processing chamber is shorter than the length from the base end to the outer circumference of the substrate held by the non-export holding end.

### BRIEF DESCRIPTION OF THE DRAWINGS

FIG. 1 is a side view of a robot device according to an embodiment of this invention.

FIG. 2 is a plan view illustrating main elements of a substrate processing device that includes a robot device.

FIGS. 3A and 3B are plan views illustrating an outline of a method for exporting a substrate whereby a free end passes through a base point.

FIGS. 4A and 4B are plan views illustrating an outline of a first export method for linearly bringing a substrate close to a base line without a free end passing through a base point.

FIGS. 5A and 5B are plan views illustrating an outline of an arm pullback amount, a hand length, an extended hand angle, and a retracted hand angle of a robot device when the first export method is used.

FIGS. 6A to 6D are timing charts illustrating changes in the various sections of a robot device when the first export method is used.

FIGS. 7A and 7B are plan views illustrating an outline of a second export method for bringing a substrate close to a base line in a circular arc without a free end passing through a base point.

FIG. 8 is a plan view illustrating an outline of a hand length, an extended hand angle, and a retracted hand angle of a robot device when the second export method is used.

FIGS. 9A to 9D are timing charts illustrating changes in the various sections of a robot device when the second export method is used.

### DETAILED DESCRIPTION OF THE INVENTION

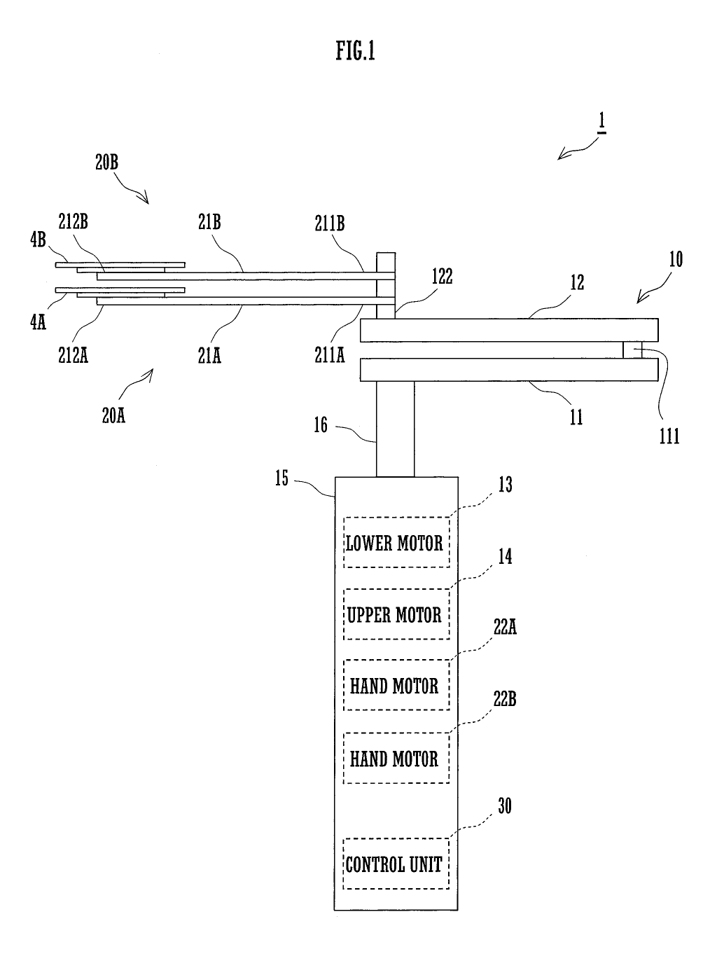

As shown in FIG. 1, a robot device 1 is provided with an arm mechanism 10, hand mechanisms 20A and 20B, and a control unit 30.

The arm mechanism 10 is provided with a lower arm 11, an upper arm 12, a lower motor 13, and an upper motor 14. The lower arm 11 and the upper arm 12 are supported relative to each other by a shaft 111 located on one end of each arm. The end section of the lower arm 11 opposite to the shaft end 111 is supported by a support pillar 15 so as to be rotatable on a base shaft 16. A shaft 122 is provided on the free end of the upper arm 12, which is the side opposite to the shaft end 111.

The lower motor 13 is contained within the support pillar 15, and rotates the lower arm 11 around the base shaft 16 in the horizontal plane via a transmission mechanism (not shown). The upper motor 14 is also contained within the support pillar 15, and rotates the upper arm 12 around the shaft 111 via a transmission mechanism (not shown). Driving the upper motor 13 and the lower motor 14 individually makes it possible to move the shaft 122 among orthogonal coordinates within the horizontal plane.

The arm mechanism 10 may be provided with an intermediate arm disposed between the lower arm 11 and the upper arm 12 and an intermediate motor that rotates the intermediate arm.

The hand mechanism 20A is provided with a hand 21A and a hand motor 22A. A support end 211A of the hand 21A is axially supported by a shaft 122, and a holding end 212A holds a substrate 4A. The hand motor 22A is contained within the support pillar 15, and rotates the hand 21A around the shaft 122 in the horizontal plane via a transmission mechanism (not shown).

The hand mechanism 20B is provided with a hand 21B and a hand motor 22B. A support end 211B of the hand 21B is axially supported by the shaft 122, and a holding end 212B holds a substrate 4B. The hand motor 22B is contained within the support pillar 15, and rotates the hand 21B around the shaft 122 in the horizontal plane via a transmission mechanism (not shown).

Driving the hand motors 22A and 22B individually moves the hands 21A and 21B independent of each other among polar coordinates in the horizontal plane.

The hand mechanisms 20A and 20B may each be provided with multiple hands in the vertical direction.

The control unit 30 generates driving data for the lower motor 13, the upper motor 14, and the hand motors 22A and 22B, and outputs that data to a motor driver (not shown). The motor driver drives the lower motor 13, the upper motor 14, and the hand motors 22A and 22B in accordance with the driving data.

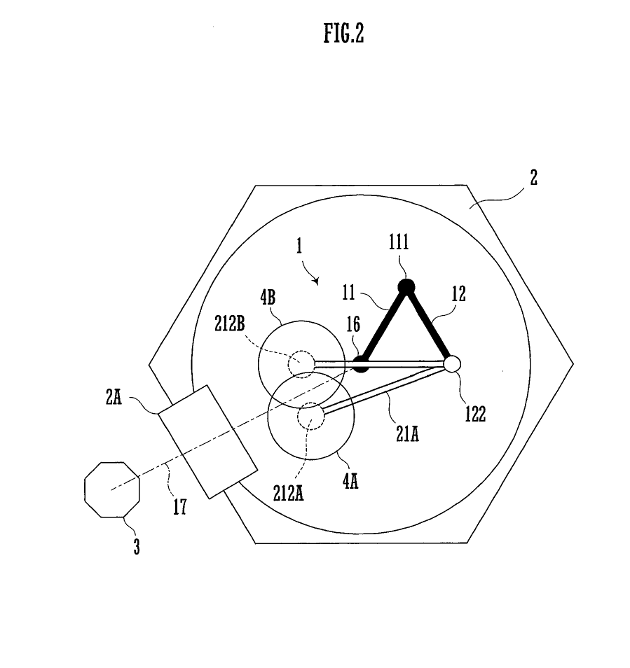

As shown in FIG. 2, the robot device 1 is installed within a processing chamber 2, and transports substrates 4 between a stage 3 outside of the processing chamber 2 and the interior of the processing chamber via a gate 2a in the processing chamber 2.

The robot device 1 is disposed so that the base shaft 16 is located in the center of the processing chamber 2. Due to the structure of the gate 2A, and in order to minimize the transport distance, the robot device 1 transports substrates 4 along a base line 17 that connects the base shaft 16 with the center of the stage 3.

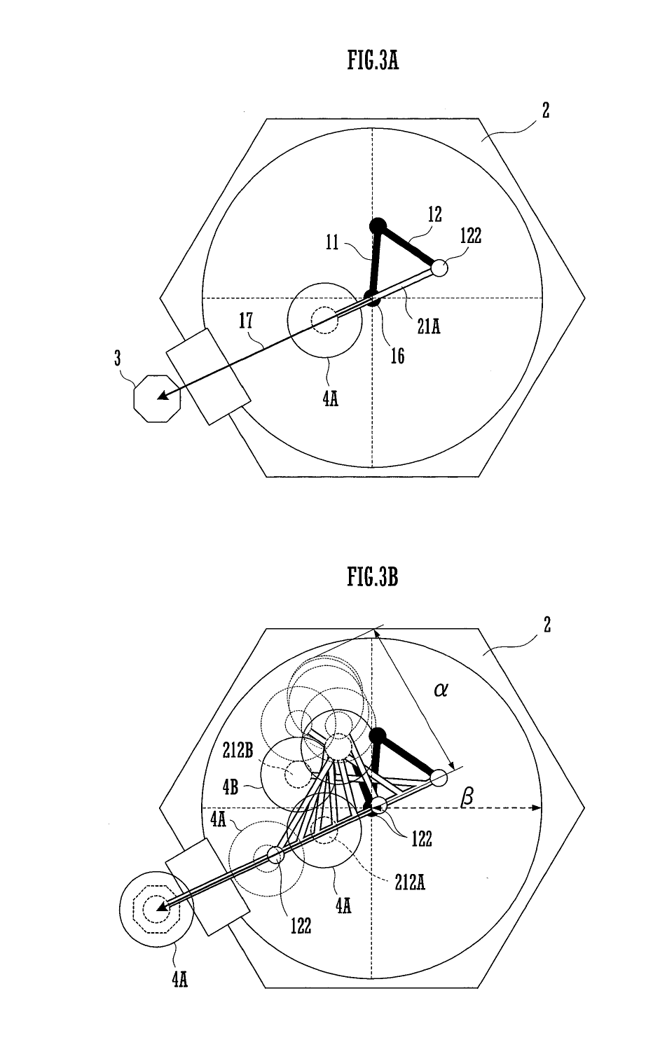

When exporting substrates so that the shaft 122 passes over the base shaft 16, the hand 21A that holds a substrate 4A to be exported and the hand 21B that holds a substrate 4B not to be exported first overlap on the base line 17, as shown in FIG. 3A. From the state, the lower motor 13 and the upper motor 14 are driven, thereby moving the lower arm 11 and the upper arm 12 so that the shaft 122 moves along the base line 17 from a point upon an extension of the base line 17, passing over the base shaft 16, as shown in FIG. 3B. Meanwhile, the hand motor 22B is driven, thereby moving the hand 21B so that the holding end 212B, which is a holding end not used for exporting, separates from the holding end 212A, which is a holding end used for exporting.

If the hand 21B is moved so that the holding end 212B separates from the holding end 212A while moving the lower arm 11 and upper arm 12 so that the shaft 122 passes over the base shaft 16, the inner diameter of the processing chamber 2 cannot be sufficiently reduced in size.

In other words, in order to prevent the substrate 4B from making contact with the inner wall of the processing chamber 2 when moving the holding end 212B among polar coordinates around the shaft 122 so as to separate from the holding end 212A, it is necessary for the inner wall of the processing chamber 2 to be located beyond of the end of the outer circumference of the substrate 4B when the shaft 122 is over the base shaft 16. Therefore, the radius β of the processing chamber 2 cannot be reduced beyond the length α in the lengthwise direction of the hand 21B from the shaft 122 to the end of the outer circumference of the substrate 4B.

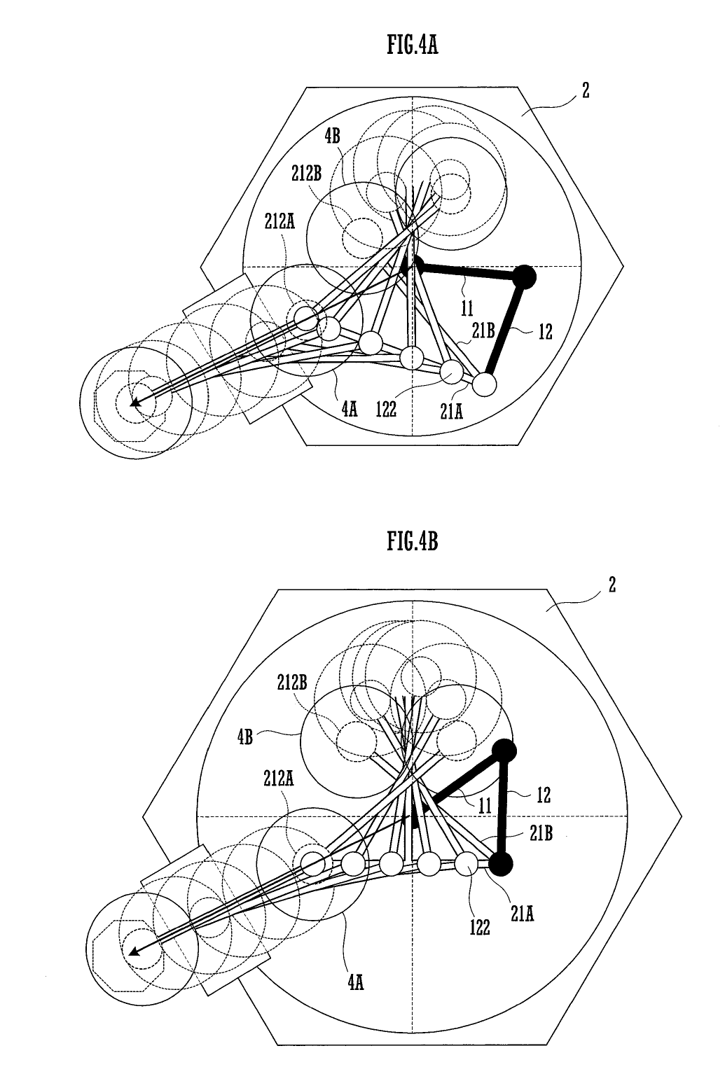

Accordingly, as shown in FIGS. 4A and 4B, the control unit 30 first positions the holding end 212A above the base line 17 in a position in which the shaft 122 is distanced from a line extending from the base line 17. From the state, the control unit 30 drives the lower motor 13 and the upper motor 14, thereby moving the lower arm 11 and the upper arm 12 so that the free end 122 linearly approaches the base line 17. Meanwhile, the control unit 30 drives the hand motor 22A, thereby moving the hand 21A so that the holding end 212A moves toward the stage 3 along the base line 17. The control unit 30 also drives the hand motor 22B, thereby rotating the hand 21B so that the holding end 212B separates from the holding end 212A.

In this manner, the hand 21B is rotated over the base line 17 by causing the holding end 212B to separate from the holding end 212A that moves along the base line 17 while linearly bringing the shaft 122 closer to the base line 17 without the shaft 122 passing over the base point 16. Therefore, the substrate 4B will not make contact with the inner wall of the processing chamber 2 even if the radius β of the processing chamber 2 is smaller than the length α in the lengthwise direction of the hand 21B from the support end 211B to the end of the outer circumference of the substrate 4B, and thus the inner diameter of the processing chamber to can be reduced.

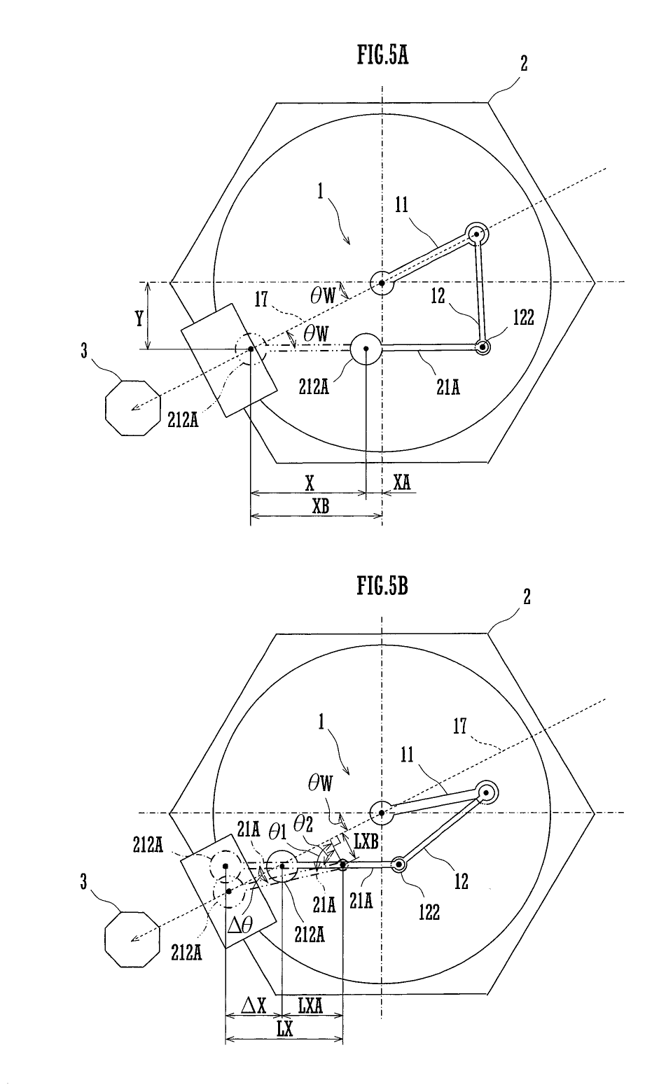

In FIGS. 5A and 5B, the following equation holds true when the arms 11 and 12 are moved, thereby moving the shaft 122 a distance X so that the holding end 212A is positioned over the base line 17:

$$X = XB - XA \\ = Y / tan θ W - XA$$

As shown in FIG. 5B, a first export method causes the hand 21A to revolve along a polar coordinate trajectory while causing the shaft 122 to move along rectangular coordinates. The hand angle Δθ at this time is found by taking the arm movement amount as ΔX, the length of the hand 21A as L, and the final hand angle as θW, as follows:

Δθ=θ1−θ2

θ2=180−90−θW=90−θW

ƒ1=cos⁻¹(B/L)

B=A·sin θW

A=L−ΔX

Based on this relationship, the hand angle Δθ is found through the following equation using the arm movement amount ΔX:

Δθ=cos⁻¹{(L−ΔX)·sin θθW/L}−(90−θW)

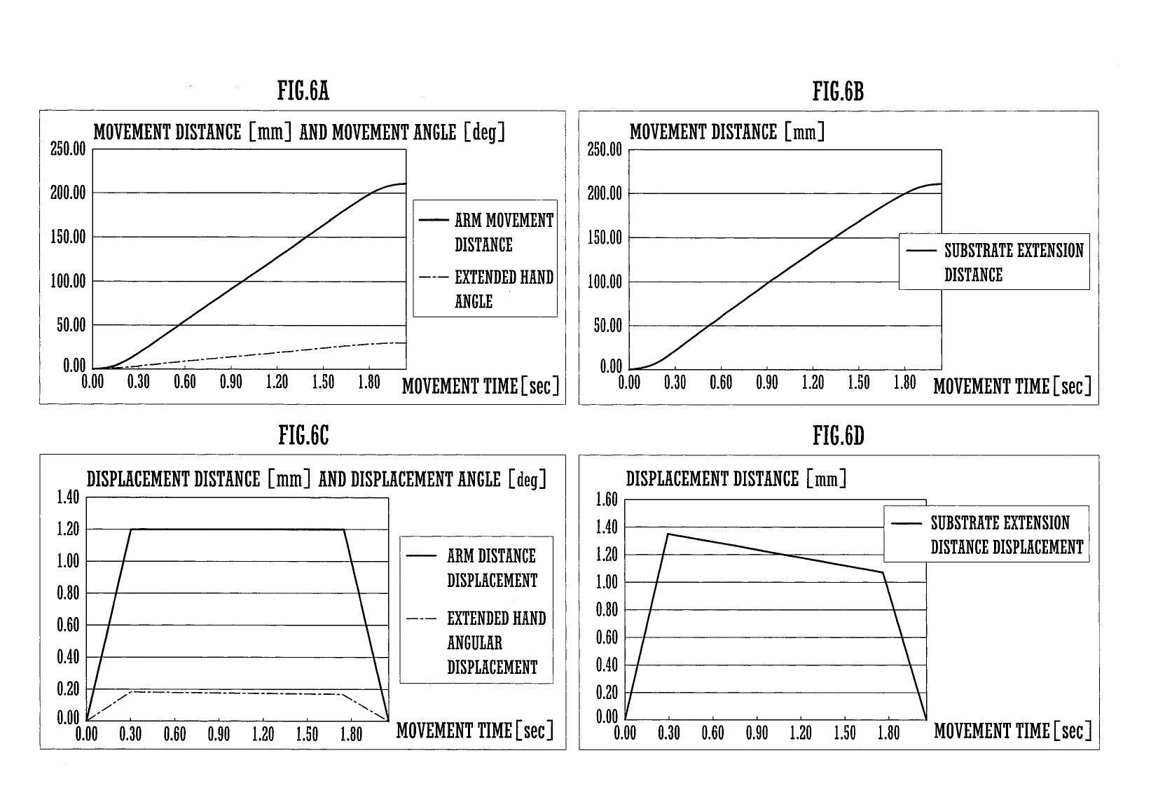

In the case where the hand length L of the hand 21A is 210 mm and the final hand angle θW is 30 deg, and assuming a maximum speed V of 120 deg/sec and an acceleration a of 400 deg/sec², the arm movement distance and angle of the extended hand 21A change as shown in FIG. 6A, and the extension distance of the substrate 4A changes as shown in FIG. 6B. In addition, the arm movement distance displacement and the angular displacement of the extended hand 21A change as shown in FIG. 6C, and the extension distance displacement of the substrate 4A changes as shown in FIG. 6D.

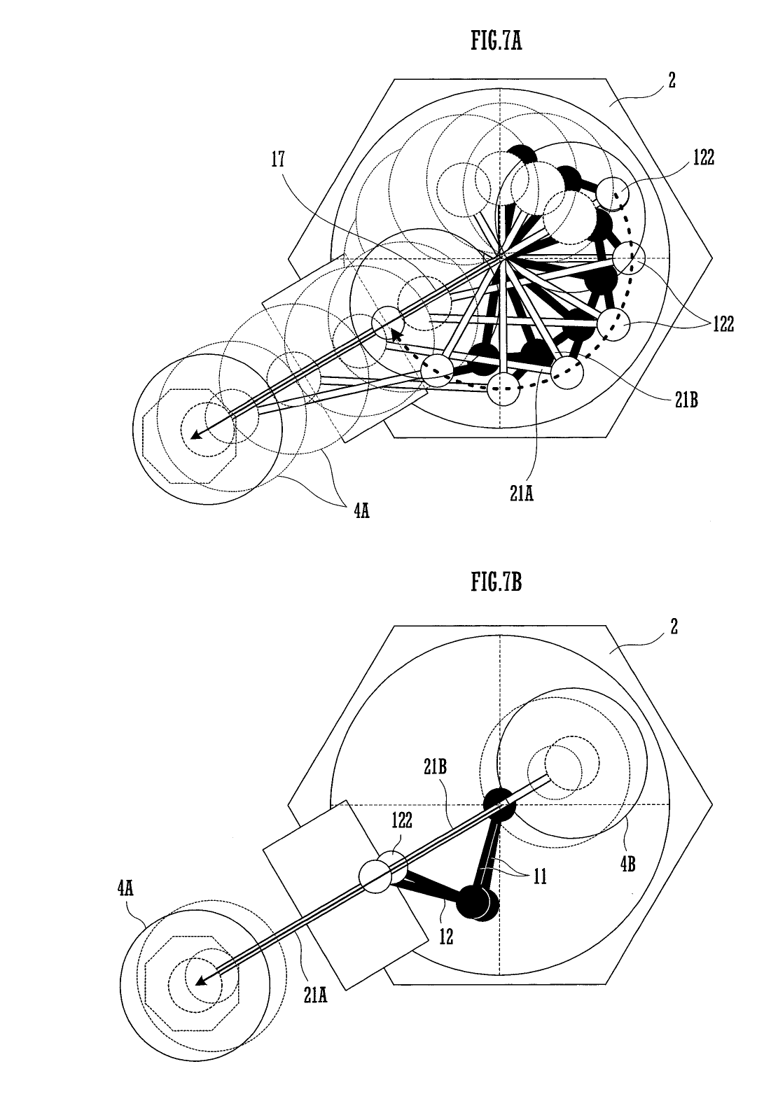

As shown in FIGS. 7A and 7B, a second export method causes the holding end 212B to separate from the holding end 212A that moves along the base line 17 while bringing the shaft 122 closer to the base line 17 in a circular arc without the shaft 122 passing over the base point 16. According to this method as well, the substrate 4B will not make contact with the inner wall of the processing chamber 2 even if the radius β of the processing chamber 2 is smaller than the length α in the lengthwise direction of the hand 21B from the support end 122B to the end of the outer circumference of the substrate 4B, and thus the inner diameter of the processing chamber to can be reduced.

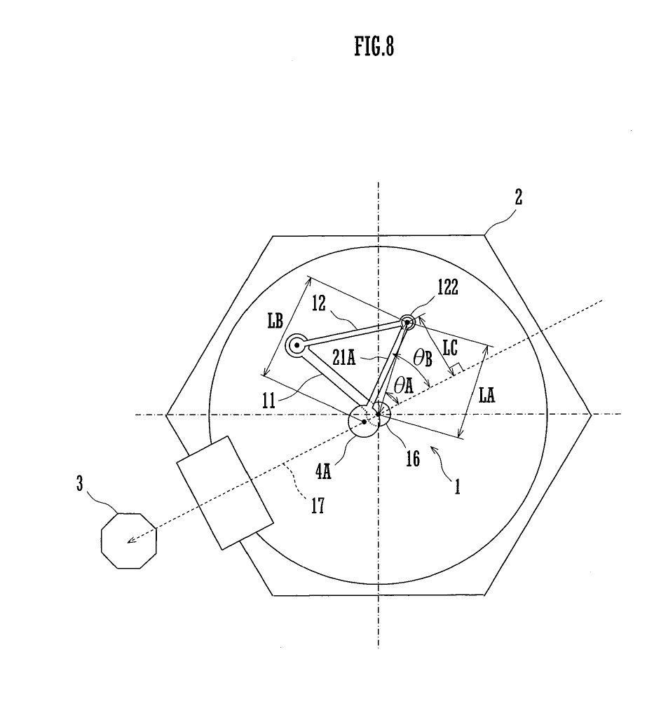

The distance LC denoted in FIG. 8 is found through the following equation, assuming that the arm pullback amount of the arms 11 and 12 are LA and the arm angle is θA:

LC=LA×sin θA

The hand angle θB is found through the following equation, assuming that the hand length of the hand 21A is LB:

$$θ B = {sin}^{- 1} ( LC / LB ) \\ = {sin}^{- 1} \{ ( LA \times sin θ A ) / LB \}$$

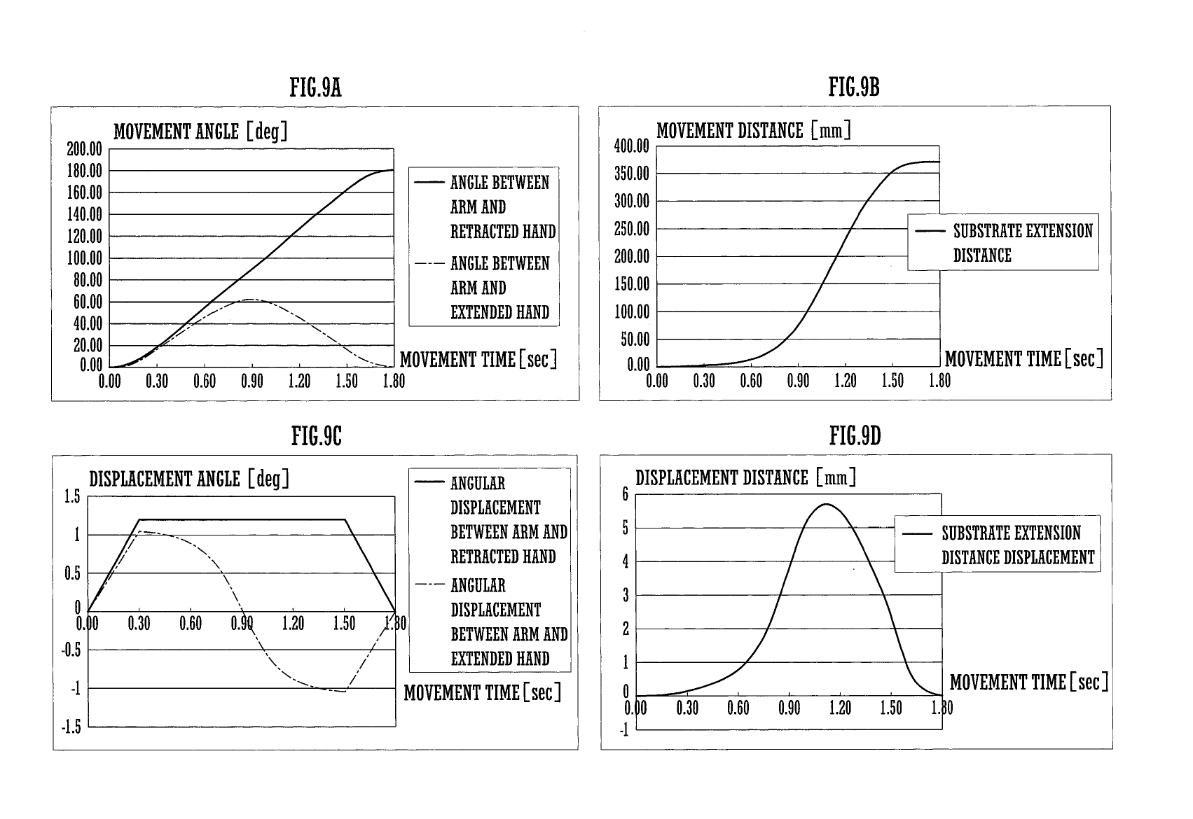

In the case where the arm pullback amount LA is 185 mm and the hand length LB of the hand 21A is 210 mm, and assuming a maximum speed V of 120 deg/sec and an acceleration a of 400 deg/sec², the angle θA between the arm and the extended hand 21A and the angle θB between the arm and the retracted hand 21B change as shown in FIG. 9A, and the extension distance of the substrate 4A changes as shown in FIG. 9B. In addition, the angular displacement between the arm and the extended hand 21A and the angular displacement between the arm and the retracted hand 21B change as shown in FIG. 9C, and the extension distance displacement of the substrate 4A changes as shown in FIG. 9D.

Although the robot device 1 is provided with two hand mechanisms 20, note that the invention is not limited thereto. Even in the case where the robot device 1 is provided with three or more hand mechanisms 20, this invention can be applied when at least two of the hand mechanisms 20 hold substrates 4 and only some of those substrates are exported from the processing chamber 2 to the stage 3.

It should be understood that the descriptions in the above embodiment are in all ways exemplary and are in no way limiting. The scope of the invention is defined not by the above embodiment but by the scope of the appended claims. Furthermore, the scope of the invention is intended to include all modifications within the scope and meaning equivalent to the scope of the appended claims.

What is claimed is:

1. A robot device, disposed within a processing chamber that performs a predetermined process on a substrate, that transports a substrate between a stage disposed outside of the processing chamber and the interior of the chamber, the device comprising:
an arm mechanism, a base end thereof rotatably supported on a base point set in a predetermined position in a horizontal plane, and a free end thereof moving among orthogonal coordinates in the horizontal plane;
a plurality of hand mechanisms, a support end of each thereof being rotatably supported by the free end and a holding end of each thereof moving among polar coordinates in the horizontal plane, each of the holding ends holding a substrate; and
a control unit that drives the arm mechanism and the hand mechanisms,
wherein, when exporting only some of a plurality of substrates held by the holding ends of at least two of the plurality of the hand mechanisms from within the processing chamber to the stage, the control unit drives the arm mechanism so that the free end approaches a base line connecting the base point with the center of the stage without passing over the base point, and drives the plurality of hand mechanisms so that one of the holding ends which is an export holding end holds a substrate to be exported and moves along the base line, and the anther holding end which is a non-export holding end holds a substrate not to be exported and separates from the export holding end.

2. The robot device according to claim 1, wherein the arm mechanism includes a lower arm whose first end, which is the base end, is supported so as to be rotatable around the base point in the horizontal plane, and an upper arm whose first end is supported by the second end of the lower arm so as to be rotatable in the horizontal plane and whose second end, which is the free end, supports the support ends of the hands so as to be rotatable in the horizontal plane.

3. The robot device according to claim 1, wherein the control unit drives the arm mechanism so that the free end approaches the base line following a linear trajectory starting from a position distanced from an extension of the base line.

4. The robot device according to claim 2, wherein the control unit drives the arm mechanism so that the free end approaches the base line following a linear trajectory starting from a position distanced from an extension of the base line.

5. The robot device according to claim 1, wherein the control unit drives the arm mechanism so that the free end approaches the base line following a circular arc-shaped trajectory.

6. The robot device according to claim 2, wherein the control unit drives the arm mechanism so that the free end approaches the base line following a circular arc-shaped trajectory.

7. A control method for a robot device disposed within a processing chamber that performs a predetermined process on a substrate and that transports a substrate between a stage disposed outside of the processing chamber and the interior of the chamber,
wherein the robot device includes:
an arm mechanism, a base end thereof being anchored to a base point in a horizontal plane and a free end thereof moving among orthogonal coordinates in the horizontal plane; and
a plurality of hand mechanisms, a support end of each thereof being rotatably supported by the free end and a holding end of each thereof moving among polar coordinates in the horizontal plane, each of the holding ends holding a substrate, and
the control method comprises:
causing, when exporting only some of a plurality of substrates held by the holding ends of at least two of the plurality of the hand mechanisms from within the processing chamber to the stage, the free end to approach a base line connecting the base point with the center of the stage without passing over the base point, while causing one of the holding ends which is an export holding end holds a substrate to be exported to move along the base line, and the anther holding end which is a non-export holding end holds a substrate not to be exported to separate from the export holding end.

8. The control method according to claim 7, wherein the arm mechanism is driven so that the free end approaches the base line following a linear trajectory starting from a position distanced from an extension of the base line.

9. The control method according to claim 7, wherein the arm mechanism is driven so that the free end approaches the base line following a circular arc-shaped trajectory.
